(19) United States
(12) Patent Application Publication
(10) Pub. No.: US 2017/0047485 A1
(43) Pub. Date: Feb. 16, 2017

(54) SUBSTRATE FOR MOUNTING LIGHT RADIATION SOURCES AND CORRESPONDING METHOD

(71) Applicant: OSRAM GmbH, Munich (DE)

(72) Inventors: Alessandro Scordino, Venezia (IT); Davide Grosso, Treviso (IT)

(21) Appl. No.: 15/231,806

(22) Filed: Aug. 9, 2016

(30) Foreign Application Priority Data
Aug. 10, 2015 (IT) 102015000043689

(51) Int. Cl. H01L 33/48; H01L 33/64; H01L 33/62

(52) U.S. Cl. CPC H01L 33/486; H01L 33/62; H01L 33/644; H01L 2933/0033; H01L 2933/0066; H01L 2933/0075

(57) ABSTRACT

A substrate for mounting electrically-powered light radiation sources, e.g. LED sources, includes a base layer of electrically-insulating material, such as PET, and a contact layer of electrically conductive material, e.g. copper. The contact layer includes a mounting area for a light radiation source having opposed anode and cathode terminals, including two portions with a gap therebetween. Therefore, the light radiation source may be mounted bridge-like across gap, with anode and cathode terminals soldered to respective soldering surfaces provided in the one and the other of said two portions of the mounting area. The latter portions include respective solder flow blocking formations including fork-shaped apertures in contact layer leaving base layer uncovered. The fork-shaped apertures have a web portion and prongs extending from web portion towards said soldering surfaces.

### CROSS-REFERENCE TO RELATED APPLICATION

This application claims priority to Italian Patent Application Serial No. 102015000043689, which was filed Aug. 10, 2015, and is incorporated herein by reference in its entirety.

### TECHNICAL FIELD

Various embodiments relates generally to lighting devices.

One or more embodiments may refer to substrates adapted to be used for the mounting of electrically-powered light radiation sources, e.g. solid state light radiation sources, such as LED sources.

### BACKGROUND

Various solutions of lighting devices employ e.g. flexible substrates, which include a base layer of an electrically insulating material, whereon there is applied a contact layer of electrically conductive material (e.g. copper) adapted to make electrical contact (for power supply, control, etc.) with the light radiation sources mounted on the substrate.

As a base layer for said substrates a polymer material may be used, such as polyethylenterephthalate (PET).

Such materials may undergo thermal shrinkage when they are exposed to temperatures such as may appear when light radiation sources such as LED sources are mounted on the substrate (for example via soldering, e.g. reflow soldering).

The material shrinkage caused by said thermal cycles may depend on various factors, such as e.g. the manufacturing process of the foil material, and may be quantified by a shrinkage factor which is expressed as a percentage, Δs %.

The shrinkage may be absent (or at least negligible) if the base layer of the electrically insulating material is covered by a layer of electrically conductive material, e.g. copper, having an appropriate thickness.

Moreover, e.g. during the mounting of LED sources via reflow soldering, the surface tension of the solder paste, if not contrasted, may cause a reduction of the electrical distance between two not-equipotential points (e.g. the anode and cathode terminals of the LED), posing the risk of originating, in the worst of cases, an undesirable solder bridge.

At least in principle, such drawbacks may be avoided by resorting to a substrate implemented as a rigid board (e.g. a Printed Circuit Board, PCB). This solution, however, is not compatible with manufacturing processes (e.g. a reel-to-reel process) which are employed for the manufacture of lighting devices having the shape of elongated (e.g. flexible) LED modules, and which therefore make use of equally flexible substrates of materials such as PET, whereon light radiation sources are mounted via soldering processes, e.g. with low-melt soldering pastes.

### SUMMARY

One or more embodiments aim at solving the previously outlined problems.

According to one or more embodiments, said object may be achieved thanks to a substrate having the features specifically set forth in the claims that follow.

One or more embodiments may also concern a corresponding method.

One or more embodiments may envisage a possible coordination of the material properties of the flexible substrate, e.g. as a function of the shrinkage factor of the base material (e.g. PET), and of the substrate geometry, e.g. the geometry of the contact terminals of the light radiation sources.

One or more embodiments may achieve one or more of the following advantages:

High speed production process,

Possibility of a continuous production,

Solder stability of the light radiation sources (e.g. LED sources),

Assembling flexibility,

Possibility of using multifunctional fixing structures, and

Non-visible fixing structure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 is a plan view of a substrate according to one or more embodiments,

FIG. 2 schematically shows the mounting of a light radiation source onto the substrate of FIG. 1;

FIG. 3 shows the surfaces destined to the mounting of such a light radiation source onto the substrate of FIG. 1; and

FIG. 4 exemplifies possible shape features of one or more embodiments.

### DETAILED DESCRIPTION

In the following description, numerous specific details are given to provide a thorough understanding of exemplary embodiments. One or more embodiments may be practiced without one or several specific details, or with other methods, components, materials, etc. In other instances, well-known structures, materials, or operations are not shown or described in detail to avoid obscuring various aspects of the embodiments.

Reference throughout this specification to “one embodiment” or “an embodiment” means that a particular feature, structure, or characteristic described in connection with the embodiment is included in at least one embodiment. Thus, the possible appearances of the phrases “in one embodiment” or “in an embodiment” in various places throughout this specification are not necessarily all referring to the same embodiment. Furthermore, particular features, structures, or characteristics may be combined in any suitable manner in one or more embodiments.

The headings provided herein are for convenience only, and therefore do not interpret the extent of protection or the scope of the embodiments.

In the Figures, reference 10 denotes a substrate which may be used for the mounting of electrically-powered light radiation sources, such as solid state sources, e.g. LED sources.

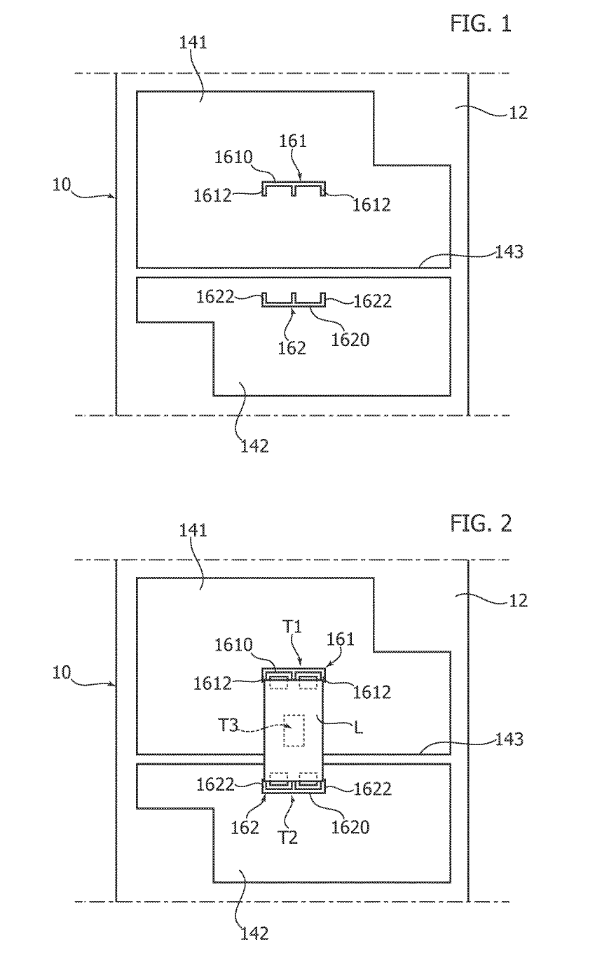

For simplicity of description, FIGS. 1 to 4 refer to the possible use of a substrate 10 for mounting one light radiation source L.

In one or more embodiments, substrate 10 may have the shape of a ribbon-like, e.g. flexible, substrate having indefinite length, which may be used for mounting a plurality of light radiation sources L. For the sake of simplicity, the Figures show a portion or section of the substrate that may be used for the mounting of one such source, denoted as L.

In one or more embodiments substrate 10, whatever the shape thereof, may include:

a base layer 12 of an electrically insulating material, such as a polymer material as polyethylenterephthalate (PET), and

a contact layer of electrically conductive material, e.g. copper, which is applied (via known techniques which therefore do not require a detailed description herein) onto base layer 12.

In the Figures there is shown an area of the contact layer destined to mounting one light radiation source L, having opposed (anode and cathode) terminals T1 and T2.

In one or more embodiments, as exemplified herein, such terminals may be split into several portions (e.g. according the solution described in the Italian Patent Application TO2014A0005752). One or more embodiments may however omit such specific implementation details of terminals T1 and T2 of source L.

The representation in FIG. 2 corresponds to an ideal plan view of substrate 10 having source L mounted thereon: terminals T1 and T2 are therefore shown partially in continuous lines (in the section projecting from the lower portion of the body or package of source L) and partially in dashed lines (in the section that is covered by the body or package of source L).

In one or more embodiments, source L may also comprise a thermal contact pad T3 (the profile whereof is shown in dashed lines in FIG. 2) adapted to facilitate the dissipation of the heat generated by source L towards the metal material of the contact layer.

In the presently shown examples, the contact layer comprises two portions 141, 142 separated by an e.g. straight gap 143.

As can be seen in the view of FIG. 2, light radiation source L may be mounted bridge-like across and above gap 143, with the anode and cathode terminals T1 and T2 which will be soldered to the first portion 141 and to the second portion 142 of the contact layer via a soldering process, e.g. the process known as reflow soldering.

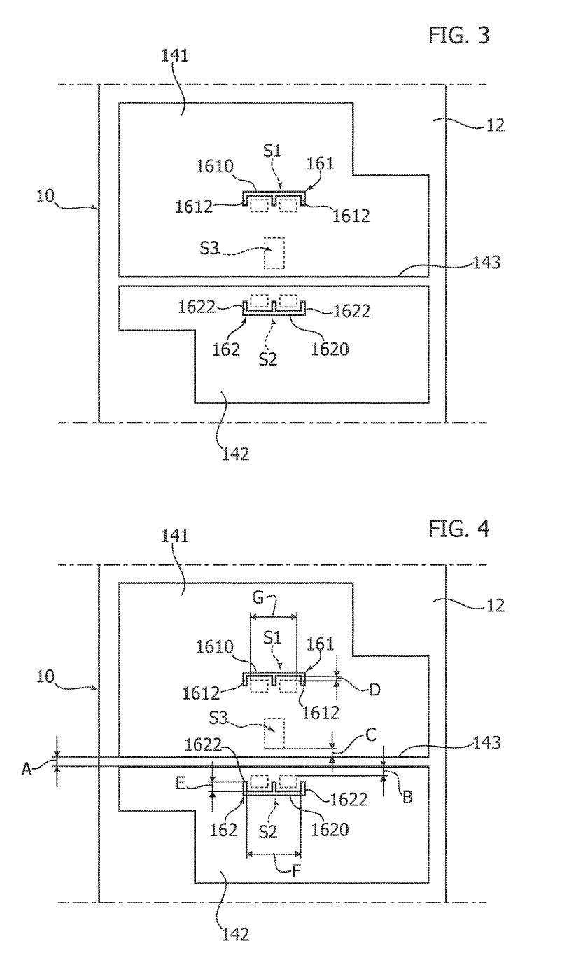

The soldering of terminals T1 and T2 may take place at respective soldering surfaces S1 and S2 (which in turn may optionally be split into two portions, in the same way as terminals T1 and T2), which are shown in dashed lines in FIGS. 3 and 4.

Such Figures show, again in dashed lines, the possibility of providing a further mounting surface S3, where it is possible to implement the contact between thermal pad T3 and the surface of the contact layer. In the presently shown example, which is solely exemplary, thermal pad T3 is located centrally with respect to source L, so as to bring about thermal contact, via portion 141, with source L largely extending above the first portion 141 of the contact layer, where soldering surface S1 and mounting surface S3 are located. It will be appreciated, however, that such choice is by no means mandatory: the mounting geometry of source L may be different, e.g. a mirror image of what shown herein.

Reference numbers 161 and 162 denote apertures or windows provided in the contact layer (respectively in first portion 141 and in second portion 142) so as to leave base layer 12 locally uncovered.

Such apertures or windows 161, 162 may be adapted to block the LED flow phenomenon previously described, which is connected to the soldering process (e.g. reflow soldering) and may prevent the consequent reduction of the electrical distance from the soldering surfaces on substrate 10, which may originate the drawbacks previously set forth in the introduction to the description.

In other words, apertures 161 and 162 act as blocking formations of the soldering flow, and correspond to areas wherein base layer 12 (e.g. a PET-based layer) is not covered by the soldering layer of an electrically conductive material (e.g. copper).

In one or more embodiments as exemplified herein, apertures or windows 161, 162 may be located externally with respect to soldering surfaces S1 and S2, i.e. on the side of soldering surfaces S1 and S2 opposed to gap 143.

In one or more embodiments, apertures 161, 162 may have a fork-like shape with two or more prongs: for example, in the presently shown instances, wherein terminals T1 and T2 are split into several portions corresponding to respective portions of soldering surfaces S1, S2, apertures 161, 162 have a shape which may be defined as a rake-like shape comprising three prongs, e.g. with one prong entering the gap between the two portions of soldering area S1 or S2.

In one or more embodiments, as presently exemplified, fork-shaped apertures or windows 161, 162 may be shaped in such a way as to “envelope”, at least in part, soldering surfaces S1 and S2.

Whatever the specific implementation details, in one or more embodiments, fork-shaped apertures 161, 162 may have a web portion 1610, 1620 wherefrom the prongs of the fork-like shape may extend towards soldering surfaces S1 and S2, i.e., in the presently shown examples, towards gap 143 between both portions 141, 142.

In one or more embodiments, as presently exemplified, fork-shaped apertures or windows 161, 162 may have symmetrical shapes, having equally long prongs.

FIG. 4 shows the geometry of FIG. 3, highlighting various size features of one or more embodiments.

Specifically, FIG. 4 highlights the following sizes:

A: extension of gap 143 separating both portions 141 and 142 of the contact layer;

B: distance of soldering surface S2 of terminal T2 to source L and gap 143 in portion 142,

C: distance of soldering surface S3 of thermal pad T3 of source L to gap 143 of portion 141,

D: distance of web portion 1610, 1620 of apertures 161 and 162 to soldering surfaces S1, S2;

E: length (extension) of the prongs of apertures 161 and 162 (such length is referred to the “inner” side of web portion 1610, 1620), if all prongs are equally long (which however is not mandatory);

F: width F of apertures 161, 162, measured as the distance between the adjacent inner sides of prongs 1612, 1622 of apertures 161, 162; if, as in the presently shown cases, apertures 161, 162 have a number of prongs higher than two, distance F is defined between the two prongs which are located more externally with respect to the aperture; and

G: width of soldering surfaces S1, S2 of terminals T1 and T2 of light radiation source L, measured cross-wise of the alignment direction of fork-shaped apertures 161, 162; if, as in the presently shown examples, surfaces S1 and S2 are split into several portions, length G is defined as the overall width, including the separation gaps between said portions.

In one or more embodiments, as regards the value of previously identified sizes D and E, it is possible to take into account the following considerations, referring to the shrinkage factor (Δs %) of the material of base layer 12:

if B<C,

B<D<Δs%*A+B

if B>C

C<D<Δs%*A+C.

In one or more embodiments, the geometry of formations 161 and 162 may be such as to prevent excessive movements of the LED during soldering, which may reduce the electrical distance, while ensuring that LED terminals do not reach beyond areas 161 and 162, which may tend to approach each other during thermal processes because of the thermal shrinkage, unchecked by metal surface, concerning gap A, reducing it according to the shrinkage factor Δs %. If the terminals should reach beyond formations 161 and 162, a proper soldering joint might not be ensured, because of the presence of electrically insulating material (e.g. PET), which is not solderable, under the terminals to be soldered.

On the basis of such considerations, as regards the value of sizes E and F, in order to effectively limit flow in the x direction (i.e. the alignment direction of blocking formations 161 and 162), E may be chosen higher than D, i.e. with the length of prongs of apertures 161 and 162 being greater than the separation distance of the soldering surfaces 161, 162 to the web portions 1610, 1620 of apertures 161, 162, so that prongs 1612, 1622 “envelop”, at least partly, such soldering surfaces S1, S2.

It is moreover possible to choose F>G, so that the separation distance between the (most) external prongs 1612, 1622 of apertures 161, 162 is greater than width G of soldering surfaces S1, S2.

In one or more embodiments (while taking into account the normal processing tolerances), the following sizes may be chosen:

A=0.35 mm

B=C=0.5 mm

which, in the presence of a shrinkage factor of Δs %=1%, may lead to 5<D<0.5035 mm.

Of course, without prejudice to the basic principles, the implementation details and the embodiments may vary, even appreciably, with respect to what has been described herein by way of non-limiting example only, without departing from the extent of protection.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A substrate for mounting electrically-powered light radiation sources, comprising:
a base layer of electrically-insulating material, and
a contact layer of electrically conductive material over said base layer, said contact layer including a mounting area for an electrically-powered light radiation source having opposed anode and cathode terminals, said mounting area including two portions with a gap therebetween for mounting said light radiation source bridge-like across said gap with said anode and cathode terminals soldered to respective soldering surfaces in the one and the other of said two portions of the mounting area,
wherein said two portions include respective solder flow blocking formations including fork-shaped apertures in said contact layer leaving said base layer uncovered; said fork-shaped apertures with a web portion and prongs extending from said web portion towards said respective soldering surfaces.

2. The substrate of claim 1, wherein said fork-shaped apertures include rake-like apertures.

3. The substrate of claim 1, wherein said soldering surfaces have a width across the alignment direction of said fork-shaped apertures and wherein said fork-shaped apertures have a distance between end prongs of the fork-shape, with said distance larger than said width.

4. The substrate of claim 1, wherein said soldering surfaces have a separation distance to the web portion of said fork-shaped apertures.

5. The substrate of claim 4, wherein said separation distance is less than the length of the prongs of said fork-shaped apertures.

6. The substrate of claim 1, wherein one of said two portions of the mounting area includes a mounting surface for a thermal pad of said lighting source, wherein said thermal pad mounting surface has a separation distance to said gap.

7. The substrate of claim 6, wherein said separation distance of said thermal pad mounting surface to said gap in one of said two portions of the mounting area is substantially equal to a distance of the terminal soldering surface to the gap in the other of said two portions of the mounting area.

8. The substrate of claim 1, wherein said base layer is flexible and/or includes polyethylenterephthalate.

9. The substrate of claim 1, wherein said contact layer includes copper.

10. A method of manufacturing a lighting device, the method comprising:
providing a substrate,
the substrate for mounting electrically-powered light radiation sources, comprising:
a base layer of electrically-insulating material, and
a contact layer of electrically conductive material over said base layer, said contact layer including a mounting area for an electrically-powered light radiation source having opposed anode and cathode terminals, said mounting area including two portions with a gap therebetween for mounting said light radiation source bridge-like across said gap with said anode and cathode terminals soldered to respective soldering surfaces in the one and the other of said two portions of the mounting area,
wherein said two portions include respective solder flow blocking formations including fork-shaped apertures in said contact layer leaving said base layer uncovered; said fork-shaped apertures with a web portion and prongs extending from said web portion towards said respective soldering surfaces,
mounting on said substrate at least one electrically-powered light radiation source, having opposed anode and cathode terminals with said light radiation source mounted bridge-like across said gap with said anode and cathode terminals soldered to said respective soldering surfaces.
